(19) United States
(12) Patent Application Publication
(10) Pub. No.: US 2008/0013375 A1
(43) Pub. Date: Jan. 17, 2008

(54) MEMORY SYSTEM

(76) Inventor: Keiichiro ENDO, Shiki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/767,894

(22) Filed: Jun. 25, 2007

(30) Foreign Application Priority Data
Jun. 30, 2006 (JP) 2006-182634

(51) Int. Cl. G11C 8/06; G11C 16/04

(52) U.S. Cl. 365/185.08

(57) ABSTRACT

A memory system includes a read only memory (ROM) which stores first data, a master control unit which generates a first address for the first data, a random access memory (RAM) which stores second data used to modify the first data, and a comparison unit which accesses the ROM and the RAM, and sends read data to the master control unit based on the first address, the read data being obtained by replacing part of the first data with the second data.

### CROSS-REFERENCE TO RELATED APPLICATIONS

This application is based upon and claims the benefit of priority from prior Japanese Patent Application No. 2006-182634, filed Jun. 30, 2006, the entire contents of which are incorporated herein by reference.

### BACKGROUND OF THE INVENTION

1. Field of the Invention

The present invention relates to a memory system with a nonvolatile semiconductor memory and, for example, to a memory system with a flash memory.

2. Description of the Related Art

Various compact memory cards have recently been developed as data storing mediums used for, for example, a digital camera or mobile telephone. When each memory card is connected to a host device such as a digital camera or cellular phone, data transmission can be performed between them.

In accordance with a recent demand for expansion of functionality, non-volatile semiconductor memories, such as flash memories, have come to be used, which can store a large amount of data, and in which data can be electrically rewritten and batch-erased.

Some of the memory cards contain a NAND-type nonvolatile semiconductor memory and controller. The controller includes a central processing unit (CPU) for controlling the entire operation of the memory card, and a read only memory (ROM) storing firmware used by the CPU.

For instance, there may be a case where when firmware has been completed, and the stage of manufacturing a memory card has been advanced to some extent before shipping, it has come to be necessary to make modifications (such as changes in functionality, or addition of a function) to eliminate defects or add improvements. In this case, the ROM of the controller, for example, may be replaced with a new one. This being so, much time, labor and/or cost is required to refine the memory card.

As a technique related to the above, Jpn. Pat. Appln. KOKAI Publication No. 2006-120082 discloses a memory card that can modify firmware stored in a ROM.

### BRIEF SUMMARY OF THE INVENTION

According to an aspect of the present invention, there is provided a memory system comprising: a read only memory (ROM) which stores first data; a master control unit which generates a first address for the first data; a random access memory (RAM) which stores second data used to modify the first data; and a comparison unit which accesses the ROM and the RAM, and sends read data to the master control unit based on the first address, the read data being obtained by replacing part of the first data with the second data.

### BRIEF DESCRIPTION OF THE SEVERAL VIEWS OF THE DRAWING

FIG. 1 is a block diagram illustrating a memory card 20 according to an embodiment of the invention;

FIG. 2 is a block diagram mainly illustrating the configuration of the address comparison unit 26 appearing in FIG. 1;

FIG. 3 is a view illustrating a data block stored in each register included in the register group 31 appearing in FIG. 2;

FIG. 4 is a view useful in explaining the content of data stored in the register group 31;

FIG. 5 is a view useful in explaining data paths for sending read data from the address comparison unit 26 to a bus master 24;

FIG. 6 is a view illustrating an example of a data block stored in the register group 31;

FIG. 7 is a view illustrating an example of data stored in a ROM 27;

FIG. 8 is a view illustrating an example of modification data stored in a RAM 28; and

FIG. 9 is a view illustrating an example of read data output from the address comparison unit 26.

### DETAILED DESCRIPTION OF THE INVENTION

An embodiment of the invention will be described with reference to the accompanying drawings. In the description below, like reference numbers denote like elements having the same function and structure. A duplicated explanation will be given only when necessary.

In the embodiment, a memory card as an example of a memory system will be described. However, the invention is not limited to this. The combination of a memory device and host device may be formed as a single large-scale integrated circuit (LSI). Namely, a controller and nonvolatile semiconductor memory, which provide a memory device, may be mounted on a printed board with the host device also mounted thereon.

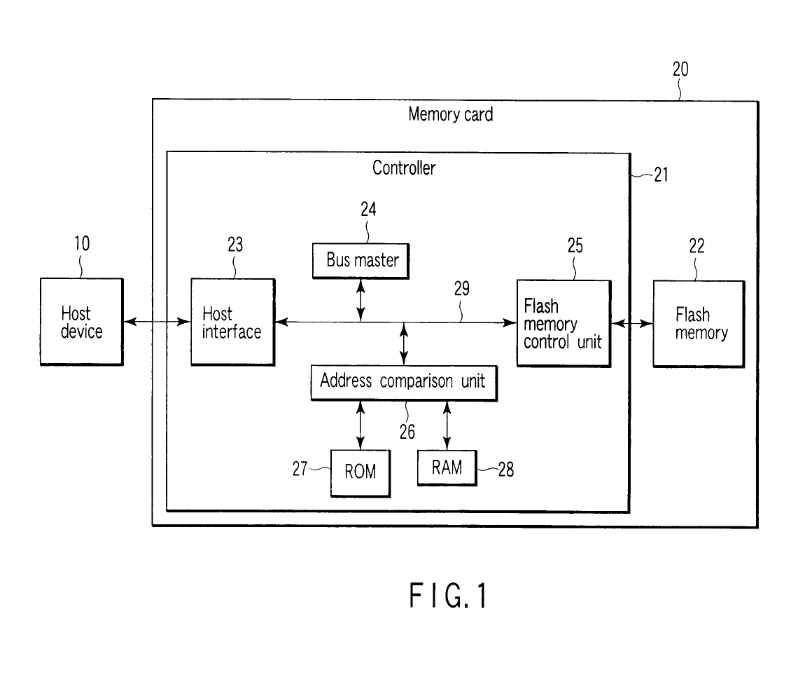

FIG. 1 is a block diagram illustrating a memory card 20 according to the embodiment of the invention. In general, the memory card 20 is used, attached to a host device 10, i.e., the memory card 20 is used as an external storing medium for the host device 10. The host device 10 is, for example, a personal computer, digital camera, or an information processing device including a cellular phone, which processes various data such as video data, audio data or identification (ID) data.

The memory card 20 includes a nonvolatile semiconductor memory 22. As the nonvolatile semiconductor memory 22, a NAND-type flash memory 22 is used, which is an electrically erasable programmable read only memory (EEPROM) that can electrically write and erase data. FIG. 1 shows a structure including a single NAND-type flash memory 22. Alternatively, two or more NAND-type flash memories 22 may be included.

The NAND-type flash memory 22 is formed of flash memory cells arranged in rows and columns. Each flash memory cell (memory cell transistor) has a laminated gate structure, in which a floating gate electrode for accumulating charge on a semiconductor substrate via a tunnel insulating film, an inter-gate insulating film and a control gate electrode are stacked. Along each column, a plurality of memory transistors similar to the above are connected in series such that a common source or drain region is used by each pair of adjacent ones of the transistors, and selective gate transistors are provided at both ends of the series connection, thereby forming a NAND-cell unit.

A plurality of NAND-cell units similar to the above are arranged along each row (along which a corresponding word line WL extends), thereby forming a block. Each block is a unit of data erasure. A plurality of memory cells included in each block and connected to the same word line WL is treated as one page. Data writing and reading is performed in units of pages.

The memory card 20 is interposed between the host device 10 and NAND-type flash memory 22, and incorporates a controller 21 for controlling the NAND-type flash memory 22 based on an instruction from the host device 10. The controller 21 comprises a host interface 23, bus master 24, flash memory control unit 25, address comparison unit 26, read only memory (ROM) 27, random access memory (RAM) 28 and bus 29.

The host interface 23 is a functional block connected to the host device 10 via a connector (not shown) and used to transmit/receive commands or data to/from the host device 10 in accordance with a preset protocol under the control of the bus master 24.

The bus master (master controller) 24 is formed of, for example, a central processing unit (CPU) or direct memory access (DMA) controller. The bus master 24 controls the entire operation of the memory card 20 via a bus 29. Further, the bus master 24 executes, upon power on, basic control of the memory card 20 based on firmware stored in, for example, the ROM 27. Yet further, the bus master 24 executes data transfer process to the NAND flash memory 22 based on a write command, read command, erase command, etc., supplied from the host device 10.

The flash memory control unit 25 is connected to the NAND flash memory 22 via a bus, and executes memory access control that is necessary for access control of the NAND flash memory 22. Specifically, the flash memory control unit 25 controls write, read and erase operations on the flash memory 22.

The ROM 27 is a nonvolatile memory and serves as a read only memory circuit. The ROM 27 stores firmware (control programs). The firmware consists of programs for executing basic control of the memory card 20.

The RAM 28 is a volatile memory circuit for temporarily storing information, information stored therein being rewritable. The RAM 28 stores part of the boot information read from the NAND flash memory 22.

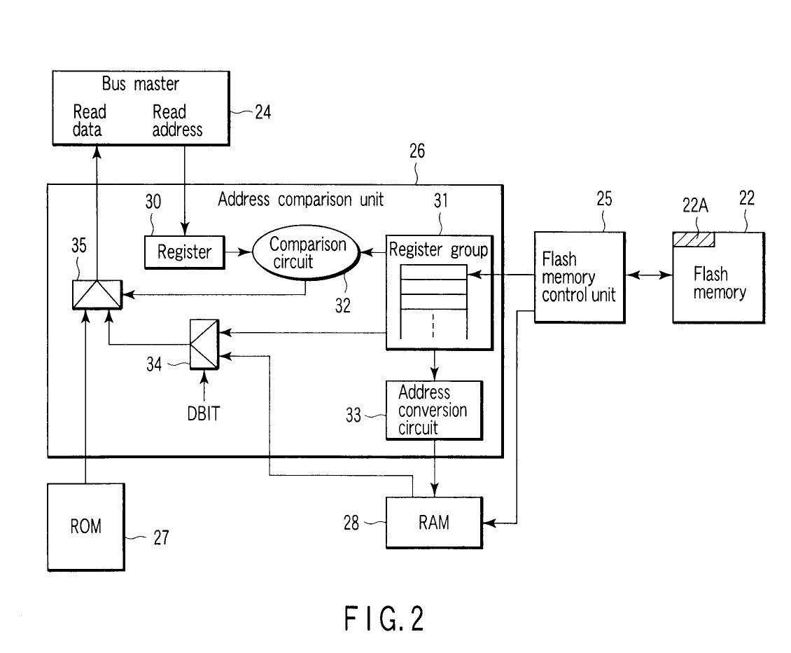

The configuration of the address comparison unit 26 will be described. The address comparison unit 26 accesses the ROM 27 and RAM 28 to send data read therefrom to the bus master 24. FIG. 2 is a block diagram mainly illustrating the configuration of the address comparison unit 26. The address comparison unit 26 comprises a register 30, register group 31, comparison circuit 32, address conversion circuit 33, first selector 34 and second selector 35.

The register 30 temporarily stores a read address sent from the bus master 24. When a read address from the bus master 24 is updated, the register 30 temporarily stores the updated read address.

The register group 31 is formed of a plurality of registers. Each register of the register group 31 temporarily stores part of the boot information sent from the NAND flash memory 22. As shown in FIG. 2, the NAND flash memory 22 has a memory area 22A for storing boot information (including part of a boot program) necessary to boot the memory card 20.

The boot information stored in the memory area 22A includes comparison addresses, modification data (e.g., modification firmware) to be replaced with part of the data (firmware) stored in the ROM 27 during booting (power on), and various flags. The boot information can be freely rewritten by the host device 10 via the controller 21.

The comparison circuit 32 compares a read address stored in the register 30 with a comparison address stored in the register group 31, and supplies the selector 35 with a control signal indicating whether the read address is identical to the comparison address.

The address conversion circuit 33 converts an address set based on the ROM 27 into an address set based on the RAM 28. Namely, a comparison address sent from the register group 31 is set based on an address space in the ROM 27. Accordingly, the address conversion circuit 33 executes address conversion to read, from the RAM 28, modification data corresponding to the address in the ROM 27.

The two input terminals of the first selector 34 receive modification data from the register group 31 and modification data from the RAM 28. Further, the control terminal of the first selector 34 receives a control signal (data flag (DBIT)) from the comparison circuit 32. Based on the control signal, the first selector 34 selects and outputs one of the two input data items.

The two input terminals of the second selector 35 receive modification data from the first selector 34 and data from the ROM 27. Further, the control terminal of the second selector 35 receives a control signal from the comparison circuit 32. Based on the control signal, the second selector 35 selects and outputs one of the two input data items.

The operation of the memory card 20 constructed as above will be described. When the memory card 20 is activated (for example, when the memory card 20 is powered by the host device 10), the bus master 24 generates read addresses corresponding to read data (e.g., firmware) to be read from the ROM 27, and sends the read addresses to the address comparison unit 26.

When the memory card 20 has been activated, the flash memory control unit 25 read boot information from the NAND flash memory 22. The boot information is sent to the address comparison unit 26 and RAM 28.

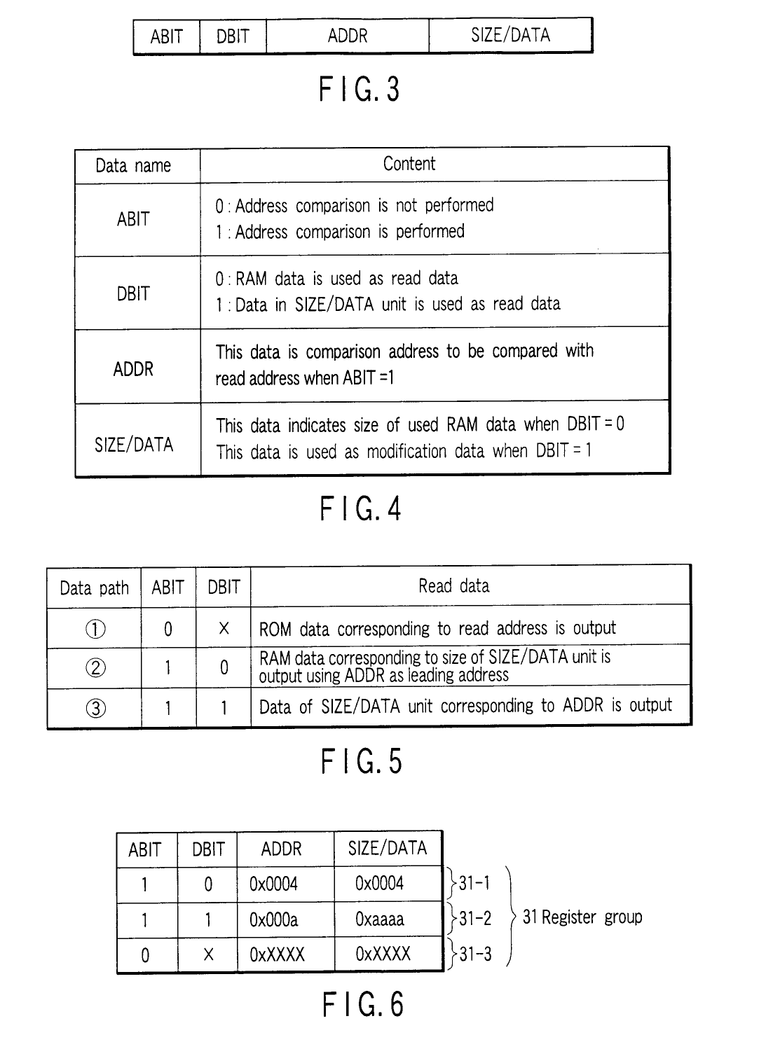

FIG. 3 is a view useful in explaining the configuration of a data block stored in each register of the register group 31. The data block comprises an address flag (ABIT), data flag (DBIT), comparison address (ADDR) and size/data (SIZE/DATA). Namely, boot information includes the address flag (ABIT), data flag (DBIT) and size/data (SIZE/DATA), as well as comparison addresses and modification data.

FIG. 4 is a view useful in explaining the content of data stored in the register group 31. The flag ABIT is used to determine whether a read address stored in the register 30 should be compared with an address ADDR stored in the register group 31. When ABIT=0, the address comparison unit 26 (more specifically, the comparison circuit 32) does not perform address comparison. In this case, the address comparison unit 26 uses, as read data, the data stored in the ROM 27 and corresponding to the read address. In contrast, when ABIT=1, the address comparison unit 26 performs address comparison. In this case, the address comparison unit 26 uses modification data as read data.

The flag DBIT is used to determine which one of the modification data items stored in the RAM 28 and the SIZE/DATA unit incorporated in the register group 31 should be used. When DBIT=0, the address comparison unit 26 uses, as read data, the modification data stored in the RAM 28. In contrast, when DBIT=1, the address comparison unit 26 uses, as read data, the modification data stored in the SIZE/DATA unit in the register group 31.

The address ADDR is a comparison address to be compared with a read address sent from the bus master 24, when ABIT=1.

The data SIZE/DATA is used as information indicating the size of data, or as modification data. Specifically, when DBIT=0, the data SIZE/DATA indicates the size of the data to be read from the RAM 28. In contrast, when DBIT=1, the data SIZE/DATA is used as modification data. Note that the initial values of each register are “ABIT=0, DBIT=0, ADDR=Don't care and SIZE/DATA=Don't care.”

The modification data included in boot information read from the NAND flash memory 22 are also stored in the RAM 28. In the embodiment, those of the modification data items read from the NAND flash memory 22, which have larger data sizes, are stored in the RAM 28. Further, the modification data items of smaller data sizes are stored in the SIZE/DATA units of the register group 31. The boundary between modification data of larger sizes and that of smaller sizes is set based on the memory capacity of each register of the register group 31.

Alternatively, all modification data may be stored in the RAM 28. In this case, each SIZE/DATA unit of the register group 31 only stores information indicating the size of the corresponding modification data read from the RAM 28.

In the embodiment, read data corresponding to a read addresses sent from the bus master 24 are output from the ROM 27, RAM 28 or register group 31. Namely, the read data are sent from the address comparison unit 26 to the bus master 24, using three data paths. FIG. 5 is a view useful in explaining data paths for sending read data from the address comparison unit 26 to the bus master 24. Which one of the first to third data paths is selected is determined from the combination of the flags ABIT and DBIT stored in an arbitrary register 31-n incorporated in the register group 31.

[First Data Path]

When ABIT=0 and DBIT=X (Don't care), the first data path is selected. In this case, address comparison is not performed by the comparison circuit 32, and an address ADDR or data SIZE/DATA is not used. The selector 35 selects read data read from the ROM 27. As a result, the address comparison unit 26 supplies the bus master 24 with the data, as read data, stored in the ROM 27 and corresponding to the read address.

[Second Data Path]

When ABIT=1 and DBIT=0, the second data path is selected. In this case, the register 31-n supplies the address conversion circuit 33 with the address ADDR stored therein and information indicating the size of the data stored in the SIZE/DATA unit of the register 31-n.

The address conversion circuit 33 converts the address ADDR based on the address space of the ROM 27, into an address based on the address space of the RAM 28. Since addresses ADDR based on the address space of the ROM 27 are often non-sequential, the RAM 28 stores modification data in relation to sequential addresses unique thereto. To read, from the RAM 28, modification data corresponding to an address ADDR, the address conversion circuit 33 performs address conversion.

The address conversion circuit 33 supplies the RAM 28 with the converted address and information indicating the size of the data. As a result, modification data, which uses the address ADDR as a leading address and has a size corresponding to that of the SIZE/DATA unit, is read from the RAM 28. The modification data read from the RAM 28 is sent to the selector 34. The selector 34 selects and outputs the modification data sent from the RAM 28, when DBIT=0.

The comparison circuit 32 compares the read address stored in the register 30 with the comparison address stored in the register 31-n. If the read address is identical to the comparison address, the comparison circuit 32 supplies the selector 35 with a control signal for selecting data sent from the selector 34. As a result, the address comparison unit 26 supplies the bus master 24 with modification data as read data, which uses the address ADDR as a leading address and has a size corresponding to that of the SIZE/DATA unit.

[Third Data Path]

When ABIT=1 and DBIT=1, the third data path is selected. In this case, the register 31-n supplies the selector 34 with the modification data stored in the SIZE/DATA unit of the register 31-n. When DBIT=1, the selector 34 selects and outputs the data sent from the register 31-n. As described above, the modification data sent via the third data path has a smaller data size than the data stored in the RAM 28.

The comparison circuit 32 compares the read address stored in the register 30 with the comparison address stored in the register 31-n. If they are identical, the comparison circuit 32 supplies the selector 35 with a control signal for selecting data sent from the selector 34. As a result, the address comparison unit 26 supplies the bus master 24 with the modification data, as read data, stored in the SIZE/DATA unit of the register 31-n.

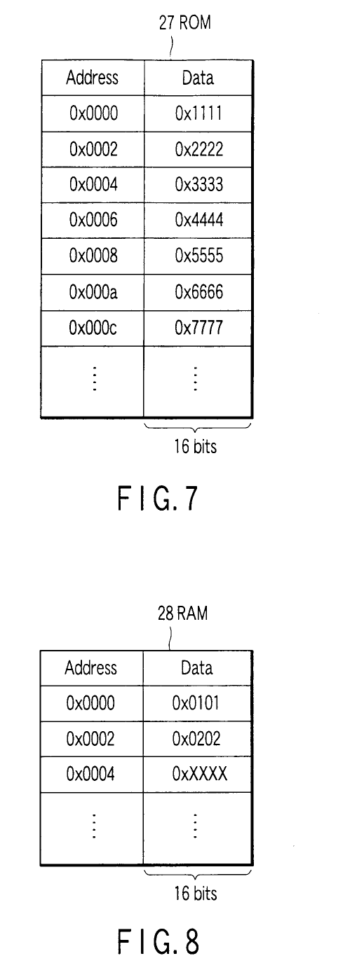

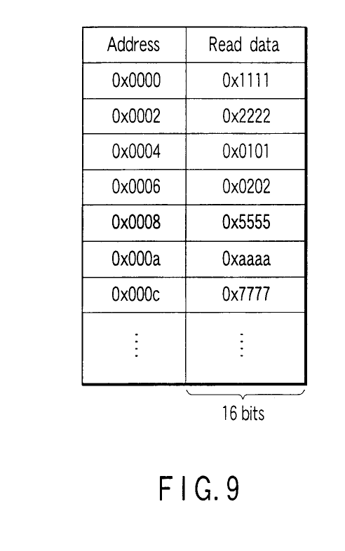

A more specific operation example of the address comparison unit 26 will be described. FIG. 6 is a view illustrating an example of a data block stored in the register group 31. FIG. 7 is a view illustrating an example of data stored in the ROM 27. FIG. 8 is a view illustrating an example of modification data stored in the RAM 28. FIG. 9 is a view illustrating an example of read data output from the address comparison unit 26. The ROM data, RAM data and read data have a data size of 16 bits (2 bytes).

The register group 31 includes a first register 31-1, second register 31-2 and third register 31-3. The first register 31-1 stores “ABIT=1, DBIT=0.” Accordingly, the address comparison unit 26 outputs the data stored in the RAM 28 and corresponding to a read address.

Specifically, the first register 31-1 stores “SIZE/DATA=0x0004.” “0x0004” indicates that the data size is 4 bytes. Since the RAM data size is 16 bits, data corresponding to two addresses are read from the RAM 28.

Further, the first register 31-1 stores “ADDR=0x0004.” Therefore, RAM data are output as read data from the address comparison unit 26, in place of the ROM data at address “0x0004” (as a leading address) and address “0x0006.”

Subsequently, the address comparison unit 26 outputs the modification data stored in the SIZE/DATA unit of the register 31-2, since the second register 31-2 stores “ABIT=1, DBIT=1.” In this embodiment, the register group 31 stores modification data with a data size of 2 bytes or less.

Specifically, the second register 31-2 stores “ADDR=0x000a.” Therefore, the modification data “0xaaaa” of the SIZE/DATA unit of the register 31-2 is output as read data from the address comparison unit 26, in place of the ROM data at address “0x000a.”

After that, the data corresponding to the read address and stored in the ROM 27 is directly output from the address comparison unit 26, since the third register 31-3 stores “ABIT=0.” Specifically, except for the above-mentioned addresses “0x0004,” “0x0006” or “0x000a,” the address comparison unit 26 outputs the data stored in the ROM 27 and corresponding to the read address.

As described above in detail, the memory card 20 includes the address comparison unit 26 that can access the ROM 27 and RAM 28. The address comparison unit 26 supplies the bus master 24 with read data obtained by replacing part of data stored in the ROM 27 with the corresponding modification data stored in the RAM 28. Further, the address comparison unit 26 stores modification data items of smaller data sizes not in the RAM 28, but in the register group 31. The address comparison unit 26 supplies the bus master 24 with read data obtained by replacing part of data stored in the ROM 27 with the corresponding modification data stored in the register group 31.

Accordingly, in the embodiment, even when it is necessary to modify the functionality of firmware (e.g., a boot program) before or after shipping a product, desired functionality modification can be realized efficiently without exchanging the ROM 27 in the controller 21 with a new one. This enables the cost and time necessary for refining the memory card 20 to be reduced significantly.

Furthermore, to read the modified firmware, it is sufficient if the bus master 24 formed of, for example, a CPU executes the normal operation of reading read data from the ROM 27. As a result, the load on the bus master 24 can be significantly reduced.

In addition, boot information is stored in the memory area 22A of the NAND flash memory 22. This enables the boot information to be rewritten freely, and hence enables the functionality of the firmware to be modified many times at low cost in a short time.

Although the embodiment employs the NAND flash memory as a nonvolatile memory, the nonvolatile memory is not limited to it. Other memories may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A memory system comprising:
a read only memory (ROM) which stores first data;
a master control unit which generates a first address for the first data;
a random access memory (RAM) which stores second data used to modify the first data; and
a comparison unit which accesses the ROM and the RAM, and sends read data to the master control unit based on the first address, the read data being obtained by replacing part of the first data with the second data.

2. The memory system according to claim 1, further comprising:
a nonvolatile memory including a plurality of nonvolatile memory cells and a memory area for storing the second data; and
a memory control unit which supplies, during booting the memory system, the RAM with the second data stored in the nonvolatile memory.

3. The memory system according to claim 2, wherein:
the nonvolatile memory stores a second address for the second data;
the memory control unit supplies the second address to the comparison unit during booting the memory system; and
the comparison unit includes a first register which stores the first address, a second register which stores the second address, and a comparison circuit which compares the first address with the second address, the comparison unit replacing the part of the first data with the second data, based on the comparison result of the comparison circuit, the part corresponding to the second address.

4. The memory system according to claim 3, wherein:
the second register stores third data sent from the nonvolatile memory along with the second address, the third data indicating a preset number of bits set for part of the second data; and
the comparison unit replaces the part of the first data with the second data in units of the preset number of bits.

5. The memory system according to claim 3, wherein:
the first address and the second address are set based on an address space for the ROM; and
the comparison unit includes an address conversion circuit which converts the second address into an address based on an address space for the RAM, and sends the converted address to the RAM.

6. The memory system according to claim 1, wherein the comparison unit includes a selector which selects one of the first data sent from the ROM and the second data sent from the RAM.

7. The memory system according to claim 2, wherein:
the nonvolatile memory stores third data for modifying the first data;
the memory control unit supplies the third data to the comparison unit during booting the memory system; and
the comparison unit includes a first register which stores the third data sent from the nonvolatile memory, the comparison unit replacing the part of the first data with the second data and the third data.

8. The memory system according to claim 7, wherein:
the nonvolatile memory stores a second address for the second data and a third address for the third data;
the memory control unit supplies the second address and the third address to the comparison unit during booting the memory system; and
the comparison unit includes a second register which stores the first address, a third register which stores the second address and the third address, and a comparison circuit which compares the first address with the second address and compares the first address with the third address, the comparison unit replacing the part of the first data with the second data and the third data, based on the comparison result of the comparison circuit, the part corresponding to the second address and the third address.

9. The memory system according to claim 7, wherein the third data has a smaller size than the second data.

10. The memory system according to claim 1, wherein the comparison unit includes a selector which selects one of the second data sent from the RAM and the third data sent from the first register.

11. The memory system according to claim 8, wherein:
the third register stores fourth data sent from the nonvolatile memory along with the second address, the fourth data indicating a preset number of bits set for part of the second data; and
the comparison unit replaces the part of the first data with the second data in units of the preset number of bits.

12. The memory system according to claim 8, wherein:
the first address and the second address are set based on an address space for the ROM; and
the comparison unit includes an address conversion circuit which converts the second address into an address based on an address space for the RAM, and sends the converted address to the RAM.

13. The memory system according to claim 7, wherein the comparison unit includes a selector which selects one of the first data sent from the ROM and the second data sent from the RAM.

14. The memory system according to claim 1, wherein the first data is firmware.

15. The memory system according to claim 1, wherein the first data is a boot program.

16. The memory system according to claim 1, wherein the nonvolatile memory is a flash memory.
